(19) United States
(12) Patent Application Publication
(10) Pub. No.: US 2011/0103016 A1
(43) Pub. Date: May 5, 2011

(54) HEAT DISSIPATION APPARATUS WITH FOOL-PROOF MECHANISM AND ELECTRONIC DEVICE INCORPORATING THE SAME

(75) Inventors: XIAN-XIU TANG, Shenzhen City (CN); ZHEN-XING YE, Shenzhen City (CN)

(73) Assignees: HONG FU JIN PRECISION INDUSTRY (ShenZhen) CO., LTD ., Shenzhen City (CN); HON HAI PRECISION INDUSTRY CO., LTD., Tu-Cheng (TW)

(21) Appl. No.: 12/639,001

(22) Filed: Dec. 16, 2009

(30) Foreign Application Priority Data
Oct. 29, 2009 (CN) 200910309030.X

(51) Int. Cl. H05K 7/20

(52) U.S. Cl. 361/697; 361/704

(57) ABSTRACT

An electronic device includes a circuit board, an electronic component mounted on the circuit board and a heat dissipation apparatus for dissipation heat generated by the electronic component. The heat dissipation apparatus includes a heat sink, at least one first supporting sleeve and a second supporting sleeve connected to a bottom side of the base of the heat sink, and a positioning sleeve mounted on the circuit board. The heat sink includes a base and a plurality of fins formed on the base. The positioning sleeve and the second supporting sleeve cooperatively form a fool-proof mechanism. The fool-proof mechanism includes a first engaging portion formed on the second supporting sleeve and a second engaging portion formed on the positioning sleeve. The heat sink can be mounted to the circuit board in a right mounting orientation only when the first engaging portion engages in the second portion of the fool-proof mechanism.

### BACKGROUND

1. Technical Field

The disclosure generally relates to heat dissipation apparatuses, and particularly to a heat dissipation apparatus with a fool-proof mechanism and an electronic device incorporating the heat dissipation apparatus.

2. Description of Related Art

As the computer technology continues to advance, electronic components of electronic devices such as central processing units (CPUs) mounted on circuit boards of computers are being made to provide faster operational speeds and greater functional capabilities. When a CPU of a computer operates at a high speed, its temperature increases rapidly. It is desirable to dissipate the generated heat of the CPU quickly, otherwise the CPU may overheat and become damaged.

Generally, heat sinks are combined with heat dissipation fans for dissipation heat generated by the CPU. The heat sink includes a base and a plurality of flat fins formed on the base. An elongated air passage is defined between every two adjacent fins. The base of the heat sink defines a plurality of through holes therein. A circuit board on which the electronic device is mounted defines a plurality of fixing holes therein corresponding to the through holes of the base of the heat sink. A plurality of securing members respectively extend through the through holes of the base and the fixing holes of the circuit board to thereby secure the heat sink to the circuit board.

When the through holes of the base of the heat sink are arranged in a square pattern, the heat sink can be mounted to the circuit board in at least two orientations. However, sometimes, the heat sink must be mounted to the circuit board in a particular orientation. For example, when the heat dissipation fan is provided at a lateral side of the heat sink, the heat sink must be mounted to the circuit board with the air passage thereof facing an air outlet of the heat dissipation fan. Thus, airflow produced by the heat dissipation fan can properly flow through the air passages of the heat sink to exchange heat with the fins. However, it is not uncommon for nonprofessional users to assemble the heat sink to the circuit board in a wrong direction, for example, the air passages of the heat sink is perpendicular to the direction of the airflow produced by the heat dissipation fan so the fins block airflow and thus heat dissipation is not effective.

Therefore, it is desirable to provide a heat dissipation apparatus with a fool-proof mechanism and an electronic device incorporating the heat dissipation apparatus.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an assembled, isometric view of an electronic device in accordance with an exemplary embodiment of the present disclosure.

FIG. 2 is an exploded, isometric view of the electronic device of FIG. 1.

FIG. 3 is a fool-proof mechanism of a heat dissipation apparatus of the electronic device of FIG. 2, viewed from another aspect.

FIG. 4 is an assembled, top plan view of a positioning member of the fool-proof mechanism and a circuit board of the electronic device of FIG. 3.

### DETAILED DESCRIPTION

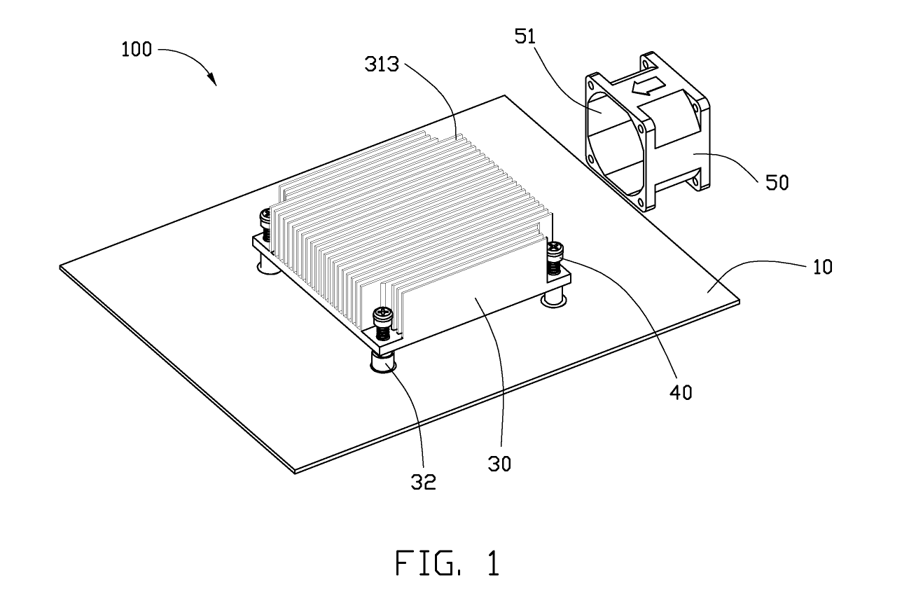

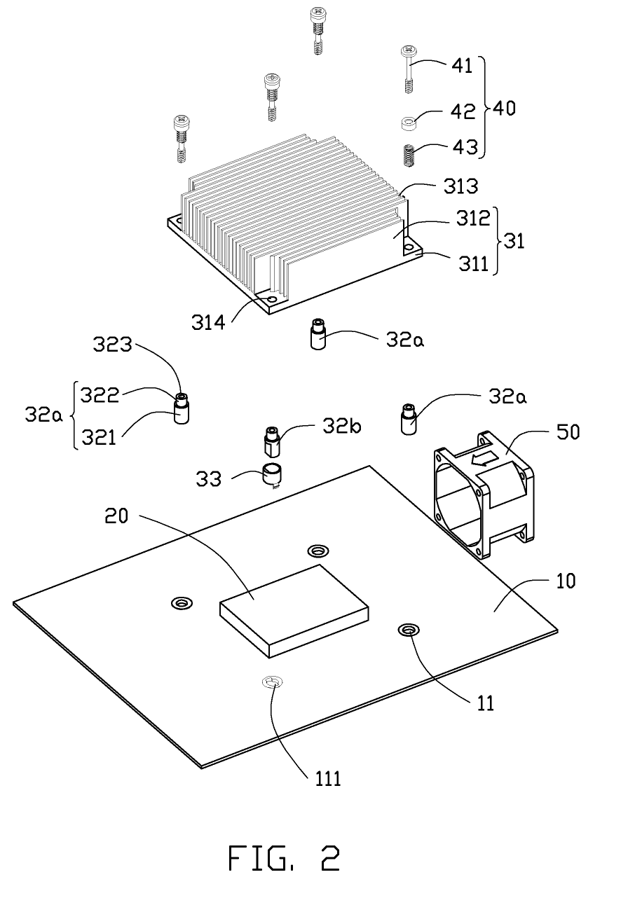

Referring to FIGS. 1-2, an electronic device 100 according to an exemplary embodiment of the present disclosure includes a circuit board 10, an electronic component 20 such as a CPU mounted on the circuit board 10, a heat dissipation apparatus 30, a plurality of securing members 40 and a heat dissipation fan 50.

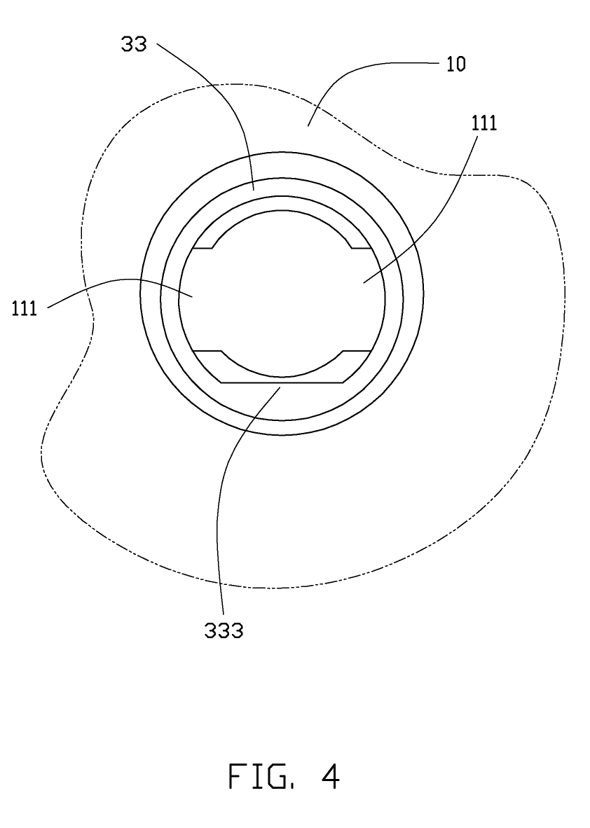

The circuit board 10 defines four circular fixing holes 11 therein for extension of the securing members 40. The four circular fixing holes 11 surround the electronic component 20 and are arranged in a square pattern. The circuit board 10 further defines two opposite cutouts 111 beside and communicating with one of the four circular fixing holes 11 (best seen in FIG. 4).

The heat dissipation apparatus 30 includes a heat sink 31, four supporting sleeves 32 and a positioning sleeve 33. The heat sink 31 is attached to the electronic component 20 for dissipating heat generated by the electronic component 20. The heat sink 31 includes a square base 311 and a plurality of parallel fins 312 formed on the base 311. The fins 312 extend integrally and upwardly from a top surface of the base 311. An air passage 313 is defined between every two adjacent fins 312. Four through holes 314 are defined in and located at four corners of the base 311 corresponding to the four fixing holes 11 of the circuit board 10. Thus the four through holes 314 of the base 311 are also arranged in a square pattern.

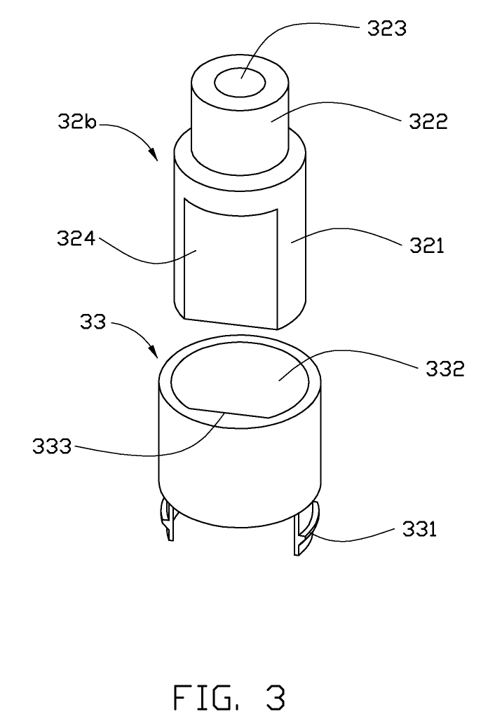

The four supporting sleeves 32 (FIG. 1) are arranged at a bottom side of the base 311 of the heat sink 31 for supporting the heat sink 31 to thereby prevent the circuit board 10 and the electronic component 20 from damaging when the heat sink 31 is mounted to the circuit board 10 too firm via the securing members 40. An axial hole 232 is defined through each supporting sleeve 32 for extension of a corresponding securing member 40. Each supporting sleeve 32 includes a supporting section 321 at a bottom end thereof and a mounting section 322 at a top end thereof. The supporting section 321 has a diameter greater than that of the mounting section 322. The mounting section 322 of each supporting sleeve 32 is inserted in a corresponding through hole 314 of the base 311 of the heat sink 31 and firmly connected to the base 311 via riveting. Due to the difference in configuration, the four supporting sleeves 32 are divided into three first supporting sleeves 32a and a second supporting sleeve 32b. The supporting section 321 of each first supporting sleeve 32a is cylindrical. Referring to FIG. 3, the supporting section 321 of the second supporting sleeve 32b is cut to define an axial positioning recess 324 in an outer surface thereof. The outer surface of the second supporting sleeve 32b forms a plane at the positioning recess 324.

Referring also to FIG. 4, the positioning sleeve 33 is mounted on the circuit board 10 and arranged at the hole 11 of the circuit board 10 beside which the two cutouts 111 are located. The positioning sleeve 33 is configured to allow the second supporting sleeve 32b engage therein only, thereby the heat sink 31 can only be mounted to the circuit board 10 in a right mounting orientation. In other words, the three first supporting sleeves 32a can not engage in the positioning sleeve 33. In this embodiment, the positioning sleeve 33 is made of plastic and defines a circular axial hole 332 through a middle portion thereof. The positioning sleeve 33 forms a positioning block 333 in an inner surface thereof corresponding to the positioning recess 324 of the second supporting sleeve 32b. The positioning block 333 extends along an axial direction of the positioning sleeve 33, thereby a plane is formed on the inner surface of the positioning sleeve 33. The positioning sleeve 33 also forms two opposite locking legs 331 at a bottom end thereof corresponding to the two opposite cutouts 111 of the circuit board 10 for mounting the positioning sleeve 33 on the circuit board 10.

Referring back to FIG. 2, each securing member 40 includes a bolt 41, a washer 42 and a spring 43. The washer 42 and the spring 43 are disposed around the bolt 41. The washer 42 is sandwiched between the spring 43 and a head of the bolt 41. The four securing members 40 respectively extend through the axial hole 323 of the four supporting sleeves 32, and then extend through the fixing holes 11 of the circuit board 10 to thereby securely attach the base 311 of the heat sink 31 to the electronic component 20. Heat generated by the electronic component 20 is absorbed by the base 311 of the heat sink 31 and then transferred to the fins 312 for dissipation.

The heat dissipation fan 50 is arranged at a right side of the heat sink 31, with an air outlet 51 thereof facing the air passages 313 of the heat sink 31. Thus, airflow produced by the heat dissipation fan 50 can properly flow through the air passages 313 of the heat sink 31 to exchange heat with the fins 312. Thus heat transferred to the fins 312 can be dissipated to the ambient atmosphere quickly.

In the heat dissipation apparatus 30 of the electronic device 100, the second supporting sleeve 32b and the positioning sleeve 33 cooperatively form a fool-proof mechanism. The positioning recess 324 of the second supporting sleeve 32b functions as a first engaging portion of the fool-proof mechanism, while the positioning block 333 of the positioning sleeve 33 functions as a second engaging portion of the fool-proof mechanism. Due to the presence of the fool-proof mechanism, the heat sink 31 can be mounted to the circuit board 10 in a right mounting orientation only when the first engaging portion (i.e., the positioning recess 324 of the second supporting sleeve 32b) engages in the second portion (i.e., the positioning block 333 of the positioning sleeve 33) of the fool-proof mechanism, thereby airflow produced by the heat dissipation fan 50 can properly flow through the air passages 313 of the heat sink 31. If the first engaging portion does not engage in the second engaging portion of the fool-proof mechanism, the heat sink 31 cannot be mounted to the circuit board 10, thereby preventing the heat sink 31 from being mounted to the circuit board 10 in a wrong orientation.

It is to be understood, however, that even though numerous characteristics and advantages of the present invention have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus for dissipating heat generated by an electronic component mounted on a circuit board, comprising:
a heat sink comprising a base and a plurality of fins formed on the base;
at least one first supporting sleeve;
a second supporting sleeve, the at least one first supporting sleeve and the second supporting sleeve being connected to a bottom side of the base of the heat sink for supporting the heat sink; and
a positioning sleeve configured for connecting with the circuit board, the positioning sleeve and the second supporting sleeve cooperatively forming a fool-proof mechanism, the fool-proof mechanism comprising a first engaging portion formed on the second supporting sleeve and a second engaging portion formed on the positioning sleeve, the heat sink being mounted to the circuit board in a right mounting orientation only when the first engaging portion engages in the second portion of the fool-proof mechanism.

2. The heat dissipation apparatus of claim 1, wherein the first engaging portion of the fool-proof mechanism is an axial positioning recess defined in an outer surface of the second supporting sleeve and the second engaging portion of the fool-proof mechanism is a positioning block form on an inner surface of the positioning sleeve.

3. The heat dissipation apparatus of claim 2, wherein the outer surface of the second supporting sleeve forms a first plane at the positioning recess, and the inner surface of the positioning sleeve forms a second plane at the positioning block.

4. The heat dissipation apparatus of claim 2, wherein the at least one first supporting sleeve and the second supporting sleeve each include a supporting section and a mounting section connected to the base of the heat sink, the positioning recess of the second supporting sleeve being defined in the supporting section thereof.

5. The heat dissipation apparatus of claim 2, wherein the positioning sleeve forms two opposite locking legs at a bottom end thereof.

6. An electronic device, comprising:
a circuit board;
an electronic component mounted on the circuit board;
a heat dissipation apparatus for dissipation heat generated by the electronic component, comprising:
a heat sink comprising a base and a plurality of fins formed on the base;
at least one first supporting sleeve;
a second supporting sleeve, the at least one first supporting sleeve and the second supporting sleeve being connected to a bottom side of the base of the heat sink for supporting the heat sink; and
a positioning sleeve mounted on the circuit board, the positioning sleeve and the second supporting sleeve cooperatively forming a fool-proof mechanism, the fool-proof mechanism comprising a first engaging portion formed on the second supporting sleeve and a second engaging portion formed on the positioning sleeve, the heat sink being mounted to the circuit board in a right mounting orientation only when the first engages portion engaging in the second portion of the fool-proof mechanism.

7. The electronic device of claim 6, wherein the first engaging portion of the fool-proof mechanism is an axial positioning recess defined in an outer surface of the second supporting sleeve and the second engaging portion of the fool-proof mechanism is a positioning block form on an inner surface of the positioning sleeve.

8. The electronic device of claim 7, wherein the outer surface of the second supporting sleeve forms a first plane at the positioning recess, and the inner surface of the positioning sleeve forms a second plane at the positioning block.

9. The electronic device of claim 6, wherein the member of the at least one first supporting sleeve are three, the three first supporting sleeves and the second supporting sleeve being arranged in a square pattern.

10. The electronic device of claim 6, further comprising a heat dissipation fan arranged at a lateral side of the heat sink, an air passage being defined between every two adjacent fins, an air outlet of the heat dissipation fan facing the air passages of the heat sink.

11. The electronic device of claim 6, wherein the positioning sleeve forms two opposite locking legs at a bottom end thereof, the positioning sleeve being mounting on the circuit board via the two opposite locking legs.

12. The electronic device of claim 6, wherein the circuit board defines a plurality of fixing holes around the circuit board, the base of the heat sink defining a plurality of through holes correspond to the fixing holes of the circuit board, the at least one first supporting sleeve and the second supporting sleeve being inserted in the through holes of the base of the heat sink.

13. The electronic device of claim 12, wherein the positioning sleeve forms two opposite locking legs at a bottom end thereof, one of the fixing holes in the circuit board having two cutouts for receiving the two locking legs of the positioning sleeve.
